(19) United States
(12) Patent Application Publication
(10) Pub. No.: US 2026/0342298 A1
(43) Pub. Date: Oct. 29, 2026

(54) LINEARIZER CIRCUITS AND METHODS FOR SWITCHES THAT ISOLATE A HIGH-SPEED DATA DRIVER FROM AN AUDIO SIGNAL AMPLIFIER

(71) Applicant: QUALCOMM Incorporated, San Diego, CA (US)

(72) Inventors: Tiancheng XIAO, Shanghai (CN); Chienchung YANG, San Diego, CA (US); Khaled Mahmoud ABDELFATTAH ALY, Irvine, CA (US); Vijayakumar DHANASEKARAN, San Diego, CA (US)

(21) Appl. No.: 19/122,183

(22) PCT Filed: Nov. 29, 2022
(86) PCT No.: PCT/CN2022/134930

§ 371 Date: Apr. 17, 2025

(51) Int. Cl. H03F 3/45; H04R 3/00

(52) U.S. Cl. CPC H03F 3/45475; H04R 3/00; H03F 2200/03; H04R 2420/07; H04R 2420/09

(57) ABSTRACT

A system includes a plug that is shared by high-speed data and analog audio transmission. One or more switches may be included to isolate a high-speed data driver from an audio signal amplifier. Gate driving circuits may be used to turn the switches ON and OFF as well as to provide linearization during an ON state of the switches. Linearization may be achieved, at least in part, by applying an absolute value waveform as a component of the gate driving signal.

### TECHNICAL FIELD

This application relates to linearizers, and more particularly to linearizing operation of switches on audio signal lines.

### BACKGROUND

A wireless communication device is generally a small form factor device among other small form factor devices, such as tablet devices. Due to the small configuration of such devices, using the device space economically is of particular interests. In this regard, it may be desirable to convert an audio path (e.g., to a headset or speakers) on a wireless communication device from a 3.5-millimeter (mm) jack to a Universal Serial Bus (USB) version C (USB-C) port connector, as the USB-C port connector is more versatile (e.g., transmits audio, exchanges USB data, exchanges battery charger data, etc.).

Because of the additional functionality of providing audio over USB-C, the differential transmission data lines DP/DN associated with the host USB-C circuit are loaded with many components, such as switching devices coupling the differential transmission lines DP/DN to audio circuitry, an application processor (AP), a battery charger circuit, electrostatic discharge (ESD) devices, traces, flex connectors, and other circuitry. In some systems, an audio signal amplifier is serviced by a same pin as a high-speed data driver in the AP. The audio signal amplifier is expected to have a high level of capacitive loading, so there is a need in the art for circuits and techniques to isolate the AP from the capacitive loading when high-speed data is transmitted.

### SUMMARY

In one implementation, a wireless communication device includes an application processor; a first audio signal amplifier; multiplexing circuitry configured to couple the application processor and the first audio signal amplifier to a set of wires; a data and audio plug coupled to the set of wires; a first switch disposed between the first audio signal amplifier and the application processor; and a first gate driving circuit coupled to a gate of the first switch, the first gate driving circuit including a first absolute value circuit.

In another implementation, a method for operating wireless communication device having a first metal oxide semiconductor (MOSFET) switch implemented between a first audio signal amplifier and an application processor is described. The method includes isolating the first audio signal amplifier from the application processor, including applying a first gate control signal to the first MOSFET switch at a first voltage level that turns off the first MOSFET switch; and linearizing the first MOSFET switch, including applying the first gate control signal to the first MOSFET switch at a second voltage level during an on state of the first MOSFET switch, where linearizing the first MOSFET switch includes generating a first absolute value waveform from a first signal, where the first gate control signal includes the first absolute value waveform.

In another implementation, a wireless communication device includes means for running an operating system; means for amplifying analog audio signals; means for coupling the means for running the operating system and the means for amplifying analog audio signals to a set of wires; a data and audio plug coupled to the set of wires; a first transistor coupled between the means for running the operating system and the means for amplifying analog audio signals; and means for linearizing operation of the first transistor, including means for generating a gate control signal from a full-wave rectified signal.

In yet another implementation, a wireless communication device includes an application processor; a pair of audio signal amplifiers corresponding to a first audio channel and a second audio channel; a coder decoder (codec) chip having multiplexing circuitry configured to couple the application processor and the pair of audio signal amplifiers to a set of wires; a plug coupled to the set of wires; a first switch coupled between the application processor and the first audio channel; and a first gate driving circuit having an output coupled to a gate of the first switch, the first gate driving circuit configured to generate a first gate control signal that includes a first absolute value waveform.

These and additional advantages may be better appreciated through the following detailed description.

### BRIEF DESCRIPTION OF THE DRAWINGS

FIG. 1 illustrates a block diagram of an example wireless device that includes gate driving circuits, according to one implementation.

FIG. 2 illustrates an example architecture for multiplexing audio signals, high-speed data signals, and charging in a device such as the device of FIG. 1, according to one implementation.

FIG. 3 illustrates a schematic diagram of an example architecture, consistent with the implementation of FIG. 2.

FIG. 4 illustrates an example architecture, according to one implementation.

FIG. 5-6 illustrate an example gate driving circuit, operating in the current domain, which may be used in the implementation of FIG. 4.

FIG. 7 illustrates an example architecture for implementing an absolute value function in the FIG. 4 implementation, in an analog voltage domain.

FIG. 8 illustrates an example architecture for implementing an absolute value function in the FIG. 4 implementation, in a digital voltage domain.

FIG. 9 illustrates a flowchart of an example method that may be performed by the example architecture of FIG. 2.

Implementations of the present disclosure and their advantages are best understood by referring to the detailed description that follows. It should be appreciated that like reference numerals are used to identify like elements illustrated in one or more of the figures.

### DETAILED DESCRIPTION

In one example, a wireless device includes a Universal Serial Bus (USB) Type-C (USB-C) receptacle that is used for charging, for high-speed data, and for analog audio signals. For instance, the device may omit a 3.5 mm audio jack in favor of using a USB-C receptacle for physical attachment of a headset or earbuds. An advantage of such devices is that they may use a single chip for USB-C and audio, thereby saving area inside the housing of the device.

However, capacitive loading attributable to an audio signal amplifier may threaten distortion of a high-speed data signal from a USB-C data driver. This is especially true if the audio signal amplifier and the USB-C data driver share a common pin on a coder decoder (codec) chip. One solution includes placing a relatively large metal oxide semiconductor field effect transistor (MOSFET) switch in line with the audio signal amplifier to allow the audio signal amplifier to be isolated from the USB-C data driver during high-speed data transmission. The solution may also include turning the MOSFET switch ON during transmission of analog audio signals. The relatively large size of the MOSFET switch may give the MOSFET switch lower ON-state resistance at the cost of higher capacitance.

A potential problem with using a relatively large MOSFET switch is that the switch itself may cause capacitive loading and, thus, distortion of the high-speed data signal. Therefore, there may be a trade-off between the audio signal amplifier being a parasitic capacitive load and the MOSFET switch being a parasitic capacitance load on the USB-C data driver path.

Various implementations include linearizing circuitry to keep ON-state resistance of a MOSFET switch within an acceptable range during normal operation so as to reduce total harmonic distortion (THD) of an analog audio signal. Such an implementation may allow a relatively large MOSFET switch to be used for effective high-speed data isolation without much or any THD penalty for the analog audio signal.

In one example, a wireless communication device includes an application processor and an audio signal amplifier coupled to a set of wires by multiplexing circuitry. A data and audio plug is coupled to the set of wires.

A switch, such as a MOSFET transistor, is disposed between the first audio signal amplifier and the application processor. The switch may operate to isolate the application processor from the audio signal amplifier during transmission of high-speed data from the application processor and may also operate to electrically couple the audio signal amplifier to the data and audio plug during analog audio transmission.

Linearization may be achieved through use of a gate driving circuit. The gate driving circuit may have an output coupled to the gate of the switch. The gate driving circuit may include a first absolute value circuit that generates a first absolute value waveform. The first absolute value circuit may generate the first absolute value waveform by applying an absolute value function to a first waveform. The first waveform may include, a digital waveform, an audio signal, a common mode voltage, or any other appropriate waveform. The first gate control signal from the first gate driving circuit includes the first absolute value waveform and may include other components as well, such as a direct current (DC) voltage, a common mode voltage, or the like.

One example implementation includes an analog circuit operating in a current domain. Another example implementation includes an analog circuit operating in a voltage domain. Yet another example implementation includes a digital circuit operating in the voltage domain.

An advantage of some implementations is high performance. Specifically, the gate control voltage may provide a more constant ON-state resistance of the transistor during audio signal transmission. The more constant ON-state resistance may lead to a higher value for THD and higher user satisfaction.

Of course, the example above is given for a single audio channel. Some implementations may include multiple (e.g., two) audio channels, and both audio channels may have a switch and a gate driving circuit to drive that switch. Such implementations are described in more detail below.

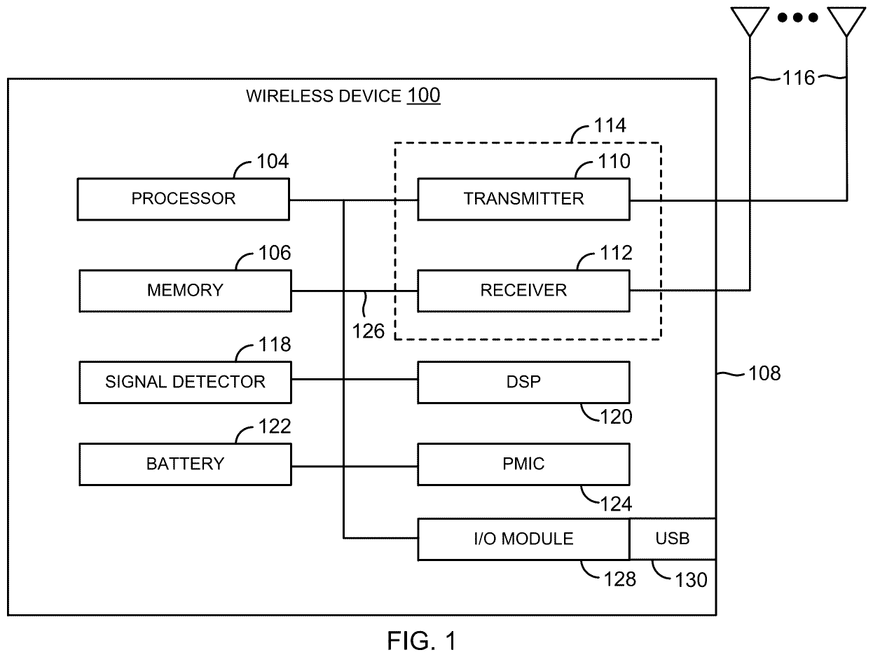

FIG. 1 illustrates an example device 100 in which aspects of the present disclosure may be implemented. The device 100 may be a battery-operated device such as a cellular phone, a handheld device, a wireless device, a laptop computer, a tablet, a smartphone, a wearable device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM).

The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114.

The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122 used to power the various components of the device 100. The device 100 may also include a power management integrated circuit (power management IC or PMIC) 124 for managing the power from the battery to the various components of the device 100. The PMIC 124 may perform a variety of functions for the device such as direct current (DC)-to-DC conversion, battery charging, power-source selection, voltage scaling, power sequencing, etc. In certain aspects, the PMIC 124 may include a battery charging circuit (e.g., a master-slave battery charging circuit) or other switched-mode power supply. The various components of the device 100 may be coupled together by a bus system 126, which may include a power bus, a control signal bus, and/or a status signal bus in addition to a data bus.

For certain aspects, the device 100 may have an input/output (I/O) module 128 for receiving and/or outputting data and/or power. In certain aspects, the I/O module 128 may include a connector 130, such as a USB Type-A (USB-A) receptacle or a USB-C receptacle. The pins of the connector 130 may be routed to the processor 104 and/or the PMIC 124 via signal lines of the bus system 126 and/or the I/O module 128, at least some of which may include an overvoltage protection circuit. Also, as described herein, the I/O module 128 may include a coder decoder (codec) chip, the codec chip including an audio signal path and drivers, among other hardware components, to facilitate audio through the connector 130.

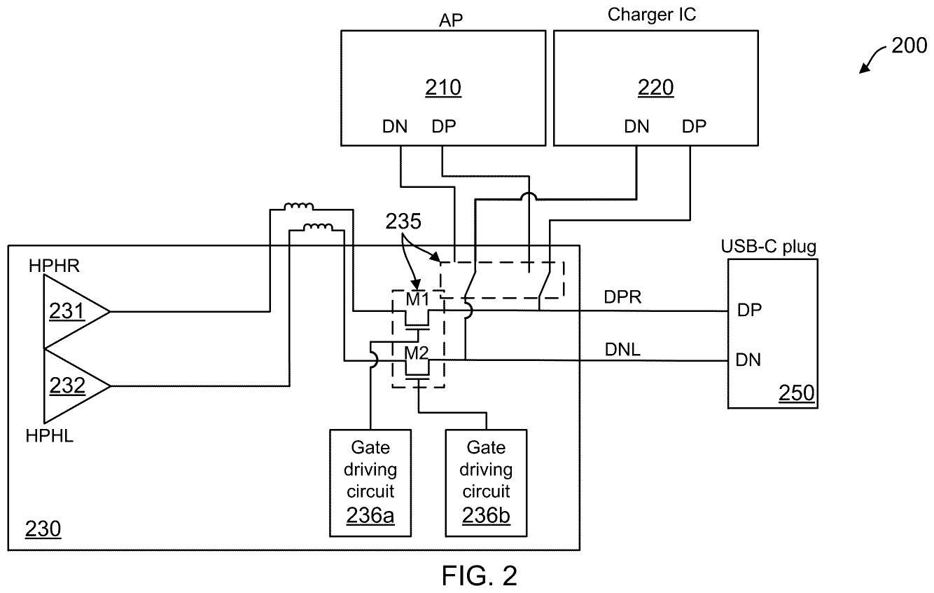

FIG. 2 is an illustration of example hardware architecture 200, which provides more detail as to how some portions of device 100 may be implemented. For instance, architecture 200 includes application processor 210, which may include some or all of the functionality of processor 104 and DSP 120. In some examples, the application processor 210 may be a system on chip (SOC), which includes multiple processor cores, a digital signal processor (DSP), memory, and the like. For instance, one or more of the processor cores may run an operating system having a kernel that provides functionality for, e.g., controlling the multiplexing circuitry 235 and the gate driving circuits 236. The architecture 200 also includes the charger integrated circuit 220, which may include some or all of the functionality of PMIC 124.

Codec chip 230 may provide some or all of the functionality of I/O module 128, and also may include connector 130 to physically interface with USB-C plug 250. In this example, plug 250 is a USB-C plug, though the scope of implementations may include any appropriate plug, whether conforming to a standard or otherwise. The codec chip 230 interfaces with both an audio signal path and a USB data path. For instance, codec chip 230 receives high-speed data on the DN and DP data lines from the USB-C plug 250. The codec chip 230 may then route that high-speed data to the application processor 210.

Additionally, the codec chip includes audio signal amplifiers 231, 232 for the right channel and left channel, respectively. Analog audio signals may be output to the USB-C plug 250 for use by, e.g., a wired headphone. Of note as well, the USB-C plug 250 may be used for charging so that DC power may be provided from the USB-C plug 250 to the charger IC 220.

To facilitate the shared connections, codec chip 230 includes multiplexing circuitry 235, which in FIG. 2 is illustrated as multiple switches. For instance, when audio signals are being transmitted from the audio signal amplifiers 231, 232 to the USB-C plug 250, switches may be turned ON to create an electrical path from the audio signal amplifiers 231, 232 to the USB-C plug 250, whereas other switches may be turned OFF to isolate the application processor 210 from the audio signal path and to isolate the charger IC 220 from the audio signal path as well. Similarly, when the application processor 210 is transmitting and receiving digital data over the DP and DN pins with the USB-C plug 250, the charger IC 220 and the audio signal amplifiers 231, 232 may be isolated from the USB-C plug 250 by the multiplexing circuitry 235. Also, when the charger IC 220 is receiving DC power over the DN and DP pins of the USB-C plug 250, the multiplexing circuitry 235 may create an electrical connection from the charger IC 220 to the USB-C plug 250 while isolating the application processor 210 and the audio signal amplifiers 231, 232 from the DC charging power. The multiplexing circuitry 235 may be controlled, e.g., by the application processor 210 or some other appropriate hardware or software logic within the architecture 200.

Multiplexing circuitry 235 may include transistors M1 and M2, which are disposed between the audio signal amplifiers 231, 232 and the application processor 210. Looking at transistor M1 first, it isolates audio signal amplifier 231 from the application processor 210 when application processor 210 is transmitting and receiving high-speed data through USB-C plug 250. Similarly, transistor M2 isolates audio signal amplifier 232 from the application processor 210 in the same way. Transistors M1 and M2 may turn ON to create electrical paths on the set of wires DPR and DNL for transmission of analog audio signals.

Gate driving circuits 236a and 236b drive the gates of transistors M1 and M2 to create OFF states during high-speed data transmission and to create a linearized ON state during transmission of analog audio signals. As noted below, gate driving circuits 236a and 236b may include circuits operable to generate absolute value (ABS) waveforms that, in part, keep ON-state resistance of transistors M1 and M2 within an acceptable range.

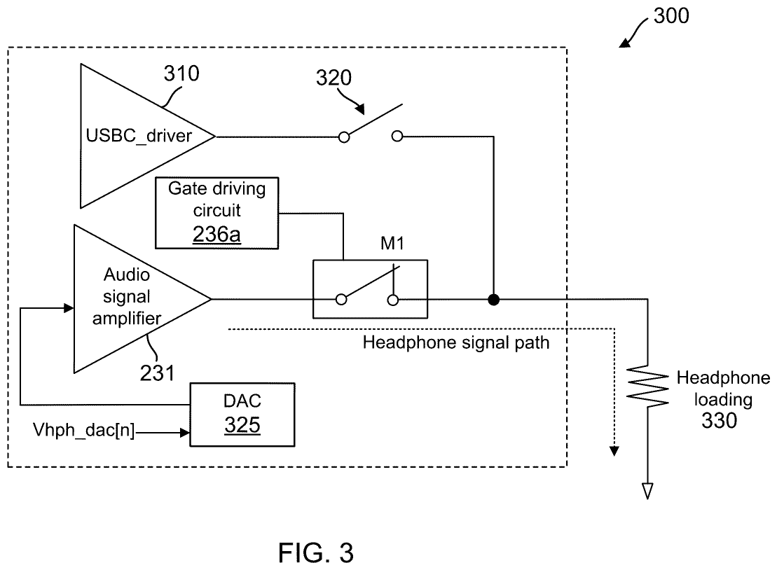

FIG. 3 illustrates a schematic diagram of an example architecture 300, consistent with the implementation of FIG. 2. FIG. 3 illustrates a relationship between the right audio channel and the application processor, including placement of transistor M1. It is understood that a same relationship exists between the left audio channel and the application processor, including placement of transistor M2.

Audio signal amplifier 231 receives an analog audio signal from DAC 325 and provides a level of gain to the analog audio signal sufficient for that audio signal to be applied to a transducer, such as a speaker in a headphone. The transducer is represented in this example by the headphone loading impedance 330. The DAC 325 receives a digital audio signal Vhph_dac[n], converts that digital audio signal to a pre-amplified audio signal, and provides the pre-amplified audio signal to the input of the audio signal amplifier 231. During transmission of analog audio signals, transistor M1 is in an ON state, thereby creating the headphone signal path. During the ON state, the gate driving circuit 236a provides a gate control signal to transistor M1 to put transistor M1 in the ON state and to provide linearization to transistor M1. During the OFF state, the gate driving circuit 236a provides the gate control signal to turn transistor MI OFF, such as by creating a negative gate-source voltage.

In various implementations described herein, transistor M1 is large enough to isolate USB-C driver 310 from audio signal amplifier 231, at least for the purposes of the particular application. Furthermore, the gate driving circuit 236a operates to provide a gate control signal to a gate of transistor M1, where that gate control signal includes a linearizing component. The linearizing component of the gate control signal may reduce or eliminate distortion that would otherwise be attributable to transistor M1.

Gate driving circuit 236b and transistor M2 operate in the same or similar way. Specifically, transistor M2 isolates audio signal amplifier 232 from USB-C driver 310 during high-speed data transmission, and transistor M2 creates a headphone signal path from audio signal amplifier 232 to the headphone loading impedance 330 during audio signal transmission. Gate driving circuit 236b provides a gate control signal the transistor M2 to turn transistor M2 either ON or OFF and to keep a resistance of transistor M2 constant or nearly constant during the ON-state.

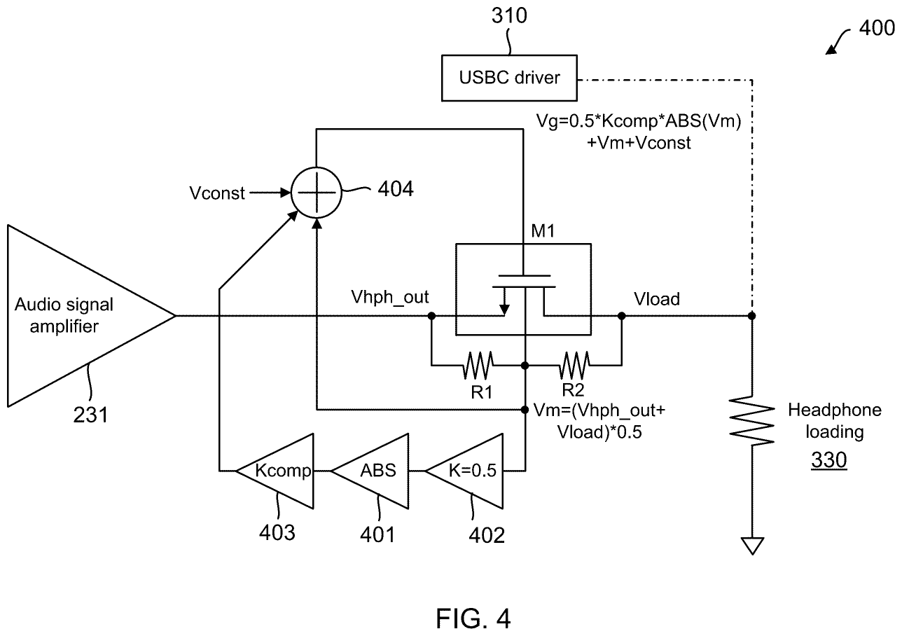

FIG. 4 is an illustration of an example architecture 400, according to one implementation of the present disclosure. Example architecture 400 focuses on the right audio channel, though it is understood that the principles apply equally to the left audio channel. Specifically, the architecture 400 illustrates a technique to linearize transistor M1 on the right audio channel, and the principles discussed with respect to architecture 400 apply just as well to linearizing transistor M2 on the left audio channel.

The gate driving circuit (e.g., gate driving circuit 236a) in architecture 400 includes absolute value circuit 401, gain elements 402 and 403, and adder 404.

Audio signal amplifier 231 is coupled to the source of transistor M1, which in this implementation is shown as a n-channel metal oxide semiconductor (NMOS) transistor. The audio signal output is labeled Vhph_out, and it is an alternating current (AC) audio signal. The signal output at the drain of transistor M1 is Vload, and Vload may be applied through USB-C plug 250 to a transducer.

The architecture 400 includes an arrangement of resistors R1 and R2, which are coupled from source to drain to provide the common mode voltage Vm.

Specifically, resistor R1 is coupled to the source of transistor M1, and resistor R2 is coupled to the drain of transistor M1. The common mode voltage Vm is applied to the body terminal of transistor M1 in this example. Vm is equal to 0.5*(Vhph_out+Vload).

The common mode voltage Vm is a waveform derived from the audio signal output (Vhph_out), and it is applied to an input of gain element 402. Gain element 402 may include an operational amplifier, a transistor, or other component appropriate to provide a gain of 0.5 in this example. Furthermore, the specific value for gain of gain element 402 may be set at any appropriate level for a given application.

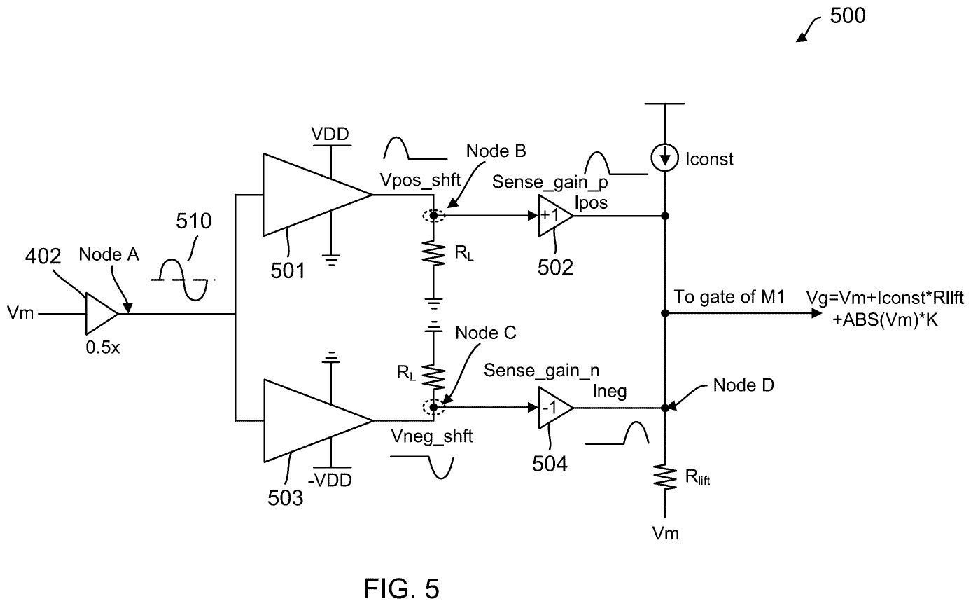

Gain element 402 makes the input voltage swing at the absolute value circuit 401 smaller to stay within a linear range of absolute value circuit 401. The output of gain element 402 is 0.5*Vm, and it is received by the input of absolute value circuit 401. In this example, absolute value circuit 401 acts as a full-wave rectifier, as described in more detail below with respect to FIGS. 5-7.

The gain element 403 may be calibrated to compensate for known process variation. In some examples, gain element 403 may be combined with gain element 402 or may be separate. The output of gain element 403 is 0.5*Kcomp*ABS(Vm), where ABS(Vm) represents the result of an absolute value function applied to the common mode voltage Vm.

The adder 404 receives the output of gain element 403, the common mode voltage, and a DC voltage offset Vconst. In this example, Vcont is a DC voltage component that is set at a level high enough to turn ON transistor M1. The common mode voltage Vm and the output of gain element 403 are both AC components.

The gate control signal Vg is output from adder 404, and it is equal to 0.5*Kcomp*ABS(Vm)+Vm+Vconst. The absolute value component (ABS(Vm)) of Vg is used to linearize the operation of transistor M1. Specifically, during the ON-state of transistor M1, the DC component of Vg keeps transistor M1 ON, and ABS(vm) changes in amplitude as the audio signal output Vhph_out changes in amplitude, thereby adjusting M1's gate-source voltage to stay relatively constant and to keep the ON-state resistance relatively constant and within a specified range.

The absolute value component of Vg has been simulated and tested and shown to reduce second-order intermodulation distortion at headphone loading impedance 330 substantially. An advantage of some implementations is that reduced second-order intermodulation distortion may further reduce third-order intermodulation distortion, where third-order intermodulation distortion is associated with a decrease in audio quality. Therefore, implementations that linearize the operation of transistor M1 may experience reduced third-order intermodulation distortion and provide higher audio quality.

FIG. 5 illustrates an example gate driving circuit 500, which may be used in the implementation of FIG. 4. The components of gate driving circuit 500 include functionality to implement gain components 402, 403, adder 404, and absolute value circuit 401. The output of gate driving circuit 500 is Vg, which may be applied to the gate of a transistor, such as transistor M1 (or transistor M2 when implemented on the left audio channel).

The common mode voltage Vm is received at the gain element 402, and the output of gain element 402 is a gain-adjusted version of Vm, which is a sinusoidal waveform 510 with positive and negative portions. Operational amplifiers 501, 503 are coupled in parallel and both receive the gain-adjusted version of Vm. Operational amplifier 501 is powered by VDD (a positive power source), whereas operational amplifier 503 is powered by an inverted power source −VDD.

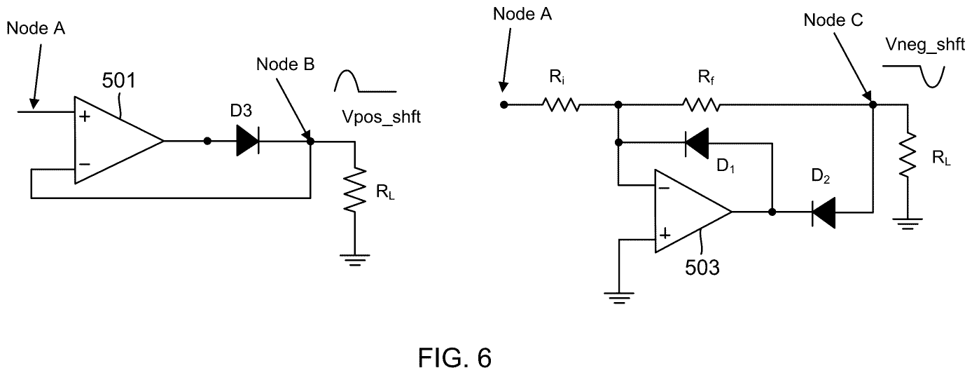

Operational amplifier 501 may be arranged as a voltage follower and, more specifically, as a half-wave rectifier. This is illustrated in more detail with respect to FIG. 6, where operational amplifier 501 is coupled by its non-inverting input to node A. The inverting input is coupled in a feedback loop to node B. Diode D3 is disposed between the output of operational amplifier 501 and node B. The voltage at node B is a positive half-wave rectified waveform Vpos_shft. In other words, Vpos_shft represents the positive half of the waveform at node A.

The operational amplifier 503 provides the negative half of the waveform at node A. FIG. 6 illustrates operational amplifier 503 in more detail. Node A is coupled to input resistor Ri, and diode D1 is coupled between resistors Ri and Rf. The cathode of diode D1, the resistor Ri, and the resistor Rf are all coupled to the inverting input of operational amplifier 503. The non-inverting input of operational amplifier 503 is coupled to ground. The output of operational amplifier 503 is coupled to the anode of diode D1 and to the cathode of diode D2. The anode of diode D2 is coupled to node C. The operational amplifier 503 is arranged as an inverting half-wave rectifier. The voltage at node C is a negative half-wave rectified waveform Vneg_shft.

Operational amplifier 501 is coupled to transconductance amplifier 502, and operational amplifier 503 is coupled to transconductance amplifier 504.

Transconductance amplifier 502 receives the positive half of the waveform, and transconductance amplifier 504 receives the negative half of the waveform.

Transconductance amplifier 502 generates Ipos, which is the positive half of the waveform in the current domain. Transconductance amplifier 504 generates Ineg, which is the negative half of the waveform in the current domain. Although not explicitly shown in FIG. 5, compensation gain may be included within transconductance amplifiers 502, 504 if appropriate.

The currents Ipos, Ineg are output from the transconductance amplifiers 502, 504, respectively. Iconst is a DC current, which corresponds to Vconst in FIG. 4. Resistor Rlift is placed at node D and coupled to the common mode voltage Vm. The currents Ipos, Ineg, Iconst are added at node D. The placement of resistor Rlift provides a voltage at node D equal to Vg, which in this example is equal to Vm+Iconst*Rlift+ABS(Vm)*k.

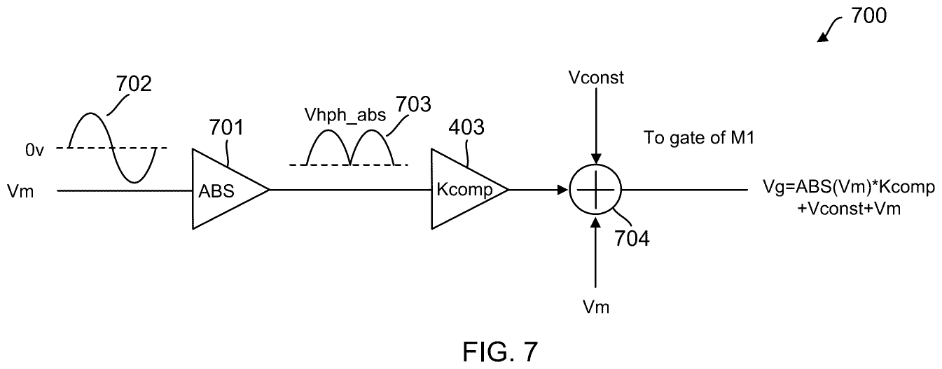

FIG. 7 illustrates an example architecture 700 for implementing the absolute value function in the FIG. 4 implementation. Architecture 700 includes the absolute value circuit 701 receiving the common mode voltage Vm waveform 702.

Once again, the common mode voltage is an AC waveform 702 having a positive part of its cycle and a negative part of its cycle, as illustrated by waveform 702. Although not shown explicitly in FIG. 7, some implementations may include a gain element, such as gain element 402, to limit the input range for the absolute value circuit 701.

In the example of FIG. 7, absolute value circuit 701 may be implemented using any suitable hardware. For instance, any full-wave rectifier now known or later developed, which is appropriate for a given application, may be used in some implementations. The output of absolute value circuit 701 is absolute value waveform 703, which is also referred to as Vhph_abs.

The absolute value waveform 703 is input to gain element 403, and the output of gain element 403 is provided to adder 704. Adder 704 receives DC voltage Vconst, common mode voltage Vm, and the output of gain element 403. In this example, the gate voltage Vg is equal to ABS(Vm)*Kcomp+Vconst+Vm.

As with the implementations of FIGS. 4-6, the principles of FIG. 7 may be adapted to the left audio channel by using the common mode voltage of M2 and applying its respective Vg to the gate of M2.

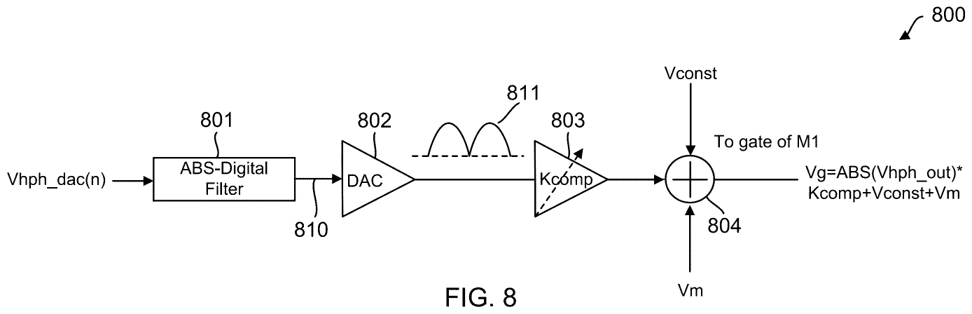

FIG. 8 is an illustration of example architecture 800, according to one implementation. Architecture 800 includes voltage rectification in the digital domain.

The digital audio signal Vhph_dac[n] (as shown in FIG. 3) may be separately sent to absolute value digital filter 801 in parallel to being sent to DAC 325 (not shown). Digital filter 801 may be implemented using hardware and/or software as appropriate. Digital filter 801 applies digital functions to generate a digital signal 810 representing an audio signal having undergone rectification. The digital signal 810 is received by DAC 802, which outputs analog signal 811. Analog signal 811 is, in this example, a rectified version of Vhph_out.

The analog signal 811 may be further gain-adjusted either up or down as appropriate by gain element 803. Gain element 803 is illustrated as an adjustable gain element, and any of the gain elements 402, 403, 803 may be adjustable if appropriate for a given application. Adder 804 receives the output from gain element 803, the common mode voltage Vm, and the DC offset Vconst. The gate control voltage Vg is equal to ABS(Vhph_out)*Kcomp+Vconst+Vm.

The architecture 800 may be implemented within the architecture 400 with a few changes to the architecture 400. For instance, the architecture 400 may be modified so that the common mode voltage Vm is not applied to gain element 402.

Rather, gain element 402 may be eliminated, and absolute value circuit 401 may be implemented using the ABS digital filter 801 and the DAC 802. Digital domain linearization may also be performed on the left audio channel for transistor M2 and audio signal amplifier 232.

Various implementations may include advantages over other solutions.

For instance, the linearization circuits and techniques described herein may operate to reduce a range within which ON-state resistance fluctuates during transmission of analog audio signals within transistors M1 and M2. For instance, experimentation and simulation has shown that a range of ON-state resistance may be reduced by approximately an order of magnitude versus a range of ON-state resistance for a system that uses a non-rectified version of Vhph_out in a gate control signal. In other words, the linearization circuits and techniques may keep the ON-state resistance of transistors M1 and M2 substantially constant during normal operation, thereby providing enhanced total harmonic distortion (THD) performance. Various implementations may include further components downstream of transistors M1 and M2, where those downstream components would be expected to increase an amount of THD. However, reducing THD at the transistors M1 and M2 may result in reduced total THD at those downstream components. Reduced total THD may lead to higher audio fidelity and greater user satisfaction.

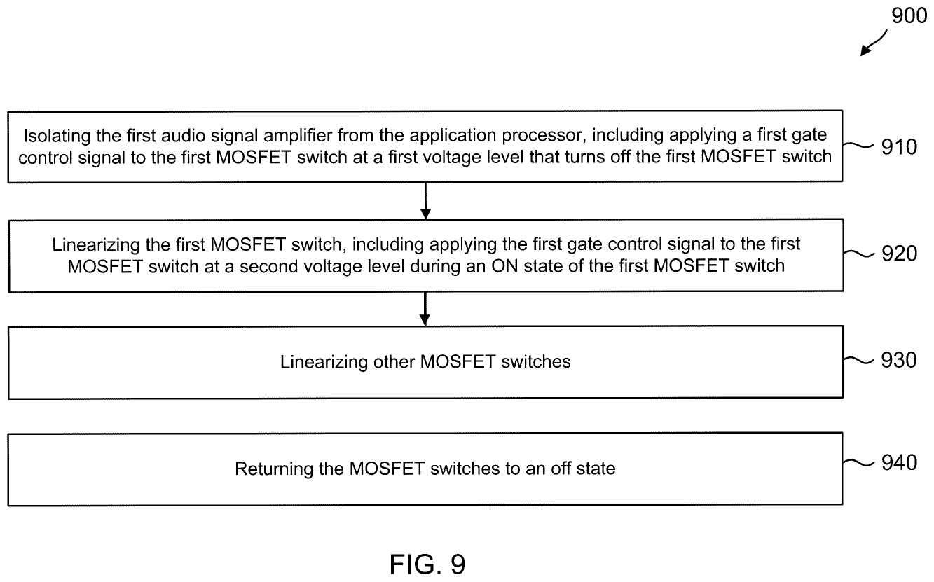

An example method for operating a wireless communication device having a first MOSFET switch implemented between a first audio signal amplifier and an application processor will now be discussed with reference to the flowchart shown in FIG. 9. The method 900 may be performed by a hardware architecture, such as is illustrated in FIG. 2, as it receives and transmits audio signals on transmission lines.

For instance, the hardware architecture may include one or more high-speed data transmission lines (e.g., DPR and DNL) that are configured for transmitting audio signals and are coupled with multiplexing circuitry (e.g., multiplexing circuitry 235) and audio signal amplifiers (e.g., audio signal amplifiers 231, 232). The first MOSFET switch may be disposed between the audio signal amplifier and the application processor to isolate the application processor from the audio signal amplifier during high-speed data transmission. The actions of the method 900 may be performed under control of logic, such as may be implemented in a kernel of application processor 210 or under control of other suitable computing circuitry.

At action 910, the method includes isolating the first audio signal amplifier from the application processor. Action 910 may include applying a first gate control signal to the first MOSFET switch at a first voltage level that turns OFF the first MOSFET switch. For instance, gate driving circuit 236a may output a low voltage to transistor M1, thereby turning OFF transistor M1 and isolating application processor 210 from a capacitive load attributable to audio signal amplifier 231.

Similarly, action 910 may include isolating other audio signal amplifiers, such as isolating audio signal amplifier 232 from application processor 210 by applying a low voltage to the gate of transistor M2 by action of the gate driving circuit 236b.

At action 920, the method includes linearizing the first MOSFET switch, including applying the first gate control signal to the first MOSFET switch at a second voltage level during an ON state of the first MOSFET switch. An example of action 920 includes the gate driving circuit 236a of FIG. 2 applying a gate control signal to transistor M1, where the gate control signal includes a DC voltage (Vdc) sufficient to turn transistor M1 ON and an AC component (ABS(Vm) or ABS(Vhph_out)) to linearize the operation of transistor M1 during the ON state.

Consistent with the examples of FIGS. 3-8, the AC component may be generated at least in part by applying an absolute value function to a waveform derived from an audio signal amplifier output (e.g., Vm) or to a digital audio signal.

At action 930, the method includes linearizing other MOSFET switches as well. For instance, on the left audio channel, the transistor M2 may be linearized in the same way, such as by applying an absolute value function to a waveform derived from an audio signal amplifier output or from a digital audio signal and then applying a gate control signal to the gate of M2. The gate control signal may include an absolute value waveform.

Actions 920-930 may be performed when those transistors M1 and M2 are turned ON and when the set of wires DPR, DNL conduct analog audio signals from audio signal amplifiers. As a result, the resistances of the transistors M1, M2 may be held to be approximately constant over the ranges of the audio signals.

At action 940, the MOSFET switches are returned to an OFF state. For instance, the respective gate driving circuits may apply the gate control signals to the transistors M1, M2 at voltage levels sufficient to cause negative gate-source voltages at those transistors. Action 940 may be performed when the set of wires DPR, DNL are not used to conduct analog audio signals from audio signal amplifiers.

The scope of implementations is not limited to the series of actions described with respect to FIG. 9. Rather, the actions 910-940 may be repeated as often as appropriate, dependent upon when wired audio capabilities are in use or not in use.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

Implementation examples are described in the following numbered clauses:
1. A wireless communication device comprising:
   an application processor;
   a first audio signal amplifier;
   multiplexing circuitry configured to couple the application processor and the first audio signal amplifier to a set of wires;
   a data and audio plug coupled to the set of wires;
   a first switch disposed between the first audio signal amplifier and the application processor; and
   a first gate driving circuit coupled to a gate of the first switch, the first gate driving circuit including a first absolute value circuit.
2. The wireless communication device of clause 1, wherein the first gate driving circuit is configured to generate a first absolute value waveform by applying an absolute value function to a first waveform derived from an audio signal output of the first audio signal amplifier, wherein a first gate control signal from the first gate driving circuit includes the first absolute value waveform, and wherein the first waveform derived from the audio signal output of the first audio signal amplifier comprises a common mode voltage between a source and a drain of the first switch.
3. The wireless communication device of clause 2, wherein the first gate driving circuit comprises:
   an adder configured to receive the common mode voltage, the first absolute value waveform, and a direct current (DC) voltage and output the first gate control signal to the gate of the first switch.
4. The wireless communication device of any of clauses 1-2, wherein the first audio signal amplifier corresponds to a first audio channel, and wherein the wireless communication device further comprises:
   a second audio signal amplifier corresponding to a second audio channel;
   a second switch disposed between the second audio signal amplifier and the application processor; and
   a second gate driving circuit coupled to a gate of the second switch, the second gate driving circuit including a second absolute value circuit and configured to generate a second absolute value waveform by applying the absolute value function to a second waveform derived from an audio signal output of the second audio signal amplifier, wherein a second gate control signal from the second gate driving circuit includes the second absolute value waveform.
5. The wireless communication device of any of clauses 1-4, wherein the first gate driving circuit comprises:
   a first operational amplifier powered by a first power source;
   a first transconductance amplifier coupled to the first operational amplifier;
   a second operational amplifier powered by an inverted power source;
   a second transconductance amplifier coupled to the second operational amplifier; and
   an adder coupled to the first transconductance amplifier and the second transconductance amplifier, wherein the adder is coupled to the gate of the first switch.
6. The wireless communication device of clause 5, wherein the first operational amplifier is configured as a first voltage follower, and wherein the second operational amplifier is configured as a second voltage follower.
7. The wireless communication device of clause 5, wherein the first transconductance amplifier and the second transconductance amplifier are coupled in parallel to the adder, wherein the adder comprises a direct current (DC) current source and a resistor coupled to a common mode voltage between a source and a drain of the first switch.
8. The wireless communication device of clause 5, wherein the first operational amplifier is configured as a half-wave rectifier, and wherein the second operational amplifier is configured as an inverting half-wave rectifier.
9. The wireless communication device of any of clauses 1-8, wherein the first absolute value circuit is coupled to a common mode voltage between a source and a drain of the first switch, and wherein the first gate driving circuit comprises:
   a full-wave rectifier coupled to the common mode voltage;
   an adder coupled to the full-wave rectifier, the adder further coupled to a direct current (DC) voltage and the common mode voltage, wherein an output of the adder is coupled to the gate of the first switch.
10. The wireless communication device of clause 9, wherein the full-wave rectifier comprises an analog voltage full-wave rectifier.
11. The wireless communication device of any of clauses 1-10, wherein the first audio signal amplifier, the multiplexing circuitry, and the first switch are implemented on a coder decoder (codec) chip.
12. The wireless communication device of any of clauses 1-11, wherein the data and audio plug comprises a universal serial bus (USB) plug.
13. The wireless communication device of any of clauses 1-12, further comprising:
   a coder decoder (codec) chip that includes the set of wires, the first audio signal amplifier, and the multiplexing circuitry, and wherein the first switch is included in the multiplexing circuitry.
14. A method for operating wireless communication device having a first metal oxide semiconductor (MOSFET) switch implemented between a first audio signal amplifier and an application processor, the method comprising:
   isolating the first audio signal amplifier from the application processor, including applying a first gate control signal to the first MOSFET switch at a first voltage level that turns off the first MOSFET switch; and
   linearizing the first MOSFET switch, including applying the first gate control signal to the first MOSFET switch at a second voltage level during an ON state of the first MOSFET switch, wherein linearizing the first MOSFET switch includes generating a first absolute value waveform from a first signal, wherein the first gate control signal includes the first absolute value waveform.
15. The method of clause 14, wherein generating the first absolute value waveform comprises:
   generating a half-wave rectified positive signal from the first signal;
   generating a half-wave rectified negative signal from the first signal;
   converting the half-wave rectified positive signal to a first current;
   converting the half-wave rectified negative signal to a second current; and
   adding the first current and the second current to a direct current (DC) current.
16. The method of any of clauses 14-15, wherein generating the first absolute value waveform is performed in an analog voltage domain, wherein the first absolute value waveform is added to a direct current (DC) voltage and an absolute value voltage.
17. The method of any of clauses 14-16, wherein the first signal comprises a digital audio signal, and wherein generating the first absolute value waveform is performed in a digital voltage domain, including inputting the digital audio signal to a digital filter, wherein the digital filter performs an absolute value function.
18. The method of any of clauses 14-17, wherein the first signal comprises a common mode voltage between a source and a drain of the first MOSFET switch.
19. The method of any of clauses 14-18, wherein the first MOSFET switch corresponds to a first audio channel, the method further comprising linearizing a second MOSFET switch corresponding to a second audio channel.
20. A wireless communication device comprising:
   means for running an operating system;
   means for amplifying analog audio signals;
   means for coupling the means for running the operating system and the means for amplifying analog audio signals to a set of wires;
   a data and audio plug coupled to the set of wires;
   a first transistor coupled between the means for running the operating system and the means for amplifying analog audio signals; and
   means for linearizing operation of the first transistor, including means for generating a gate control signal from a full-wave rectified signal.
21. The wireless communication device of clause 20, wherein the data and audio plug comprises a universal serial bus (USB) plug.
22. The wireless communication device of any of clauses 20-21, further comprising: a coder decoder (codec) chip that includes the set of wires, the means for amplifying analog audio signals, and the means for coupling, and wherein the first transistor is disposed on the codec chip.
23. The wireless communication device of any of clauses 20-22, wherein the means for generating the gate control signal comprises:
   a first half-wave rectifier coupled to a first transconductance amplifier; and
   a second half-wave rectifier coupled to a second transconductance amplifier.
24. The wireless communication device of any of clauses 20-23, wherein the means for generating the gate control signal comprises:
   a digital filter and a digital to analog converter (DAC) configured to generate the full-wave rectified signal from a digital audio signal.
25. The wireless communication device of any of clauses 20-24, wherein the means for generating the gate control signal comprises:
   means for generating the full-wave rectified signal in an analog digital domain from a common mode voltage of the first transistor.
26. A wireless communication device comprising:
   an application processor;
   a pair of audio signal amplifiers corresponding to a first audio channel and a second audio channel;
   a coder decoder (codec) chip having multiplexing circuitry configured to couple the application processor and the pair of audio signal amplifiers to a set of wires;
   a plug coupled to the set of wires;
   a first switch coupled between the application processor and the first audio channel; and
   a first gate driving circuit having an output coupled to a gate of the first switch, the first gate driving circuit configured to generate a first gate control signal that includes a first absolute value waveform.
27. The wireless communication device of clause 26, wherein the first switch is disposed on the codec chip.
28. The wireless communication device of any of clauses 26-27, further comprising:
   a second switch coupled between the application processor and the second audio channel; and
   a second gate driving circuit having an output coupled to a gate of the second switch, the second gate driving circuit configured to generate a second gate control signal from a second absolute value waveform.
29. The wireless communication device of any of clauses 26-28, wherein the first gate driving circuit comprises:
   a first operational amplifier (op amp) powered by a first power source;
   a first transconductance amplifier coupled to the first op amp
   a second op amp powered by an inverted power source;
   a second transconductance amplifier coupled to the second op amp; and
   an adder coupled to the first transconductance amplifier and the second transconductance amplifier, wherein the adder is coupled to the gate of the first switch.
30. The wireless communication device of clause 29, wherein the first absolute value waveform comprises a full-wave rectified version of a common mode voltage of the first switch.

1. A wireless communication device comprising:
an application processor;
a first audio signal amplifier;
multiplexing circuitry configured to couple the application processor and the first audio signal amplifier to a set of wires;
a data and audio plug coupled to the set of wires;
a first switch disposed between the first audio signal amplifier and the application processor; and
a first gate driving circuit coupled to a gate of the first switch, the first gate driving circuit including a first absolute value circuit.

2. The wireless communication device of claim 1, wherein the first gate driving circuit is configured to generate a first absolute value waveform by applying an absolute value function to a first waveform derived from an audio signal output of the first audio signal amplifier, wherein a first gate control signal from the first gate driving circuit includes the first absolute value waveform, and wherein the first waveform derived from the audio signal output of the first audio signal amplifier comprises a common mode voltage between a source and a drain of the first switch.

3. The wireless communication device of claim 2, wherein the first gate driving circuit comprises:
an adder configured to receive the common mode voltage, the first absolute value waveform, and a direct current (DC) voltage and output the first gate control signal to the gate of the first switch.

4. The wireless communication device of claim 2, wherein the first audio signal amplifier corresponds to a first audio channel, and wherein the wireless communication device further comprises:
a second audio signal amplifier corresponding to a second audio channel;
a second switch disposed between the second audio signal amplifier and the application processor; and
a second gate driving circuit coupled to a gate of the second switch, the second gate driving circuit including a second absolute value circuit configured to generate a second absolute value waveform by applying the absolute value function to a second waveform derived from an audio signal output of the second audio signal amplifier, wherein a second gate control signal from the second gate driving circuit includes the second absolute value waveform.

5. The wireless communication device of claim 1, wherein the first gate driving circuit comprises:
a first operational amplifier powered by a first power source;
a first transconductance amplifier coupled to the first operational amplifier;
a second operational amplifier powered by an inverted power source;
a second transconductance amplifier coupled to the second operational amplifier; and
an adder coupled to the first transconductance amplifier and the second transconductance amplifier, wherein the adder is coupled to the gate of the first switch.

6. The wireless communication device of claim 5, wherein the first operational amplifier is configured as a first voltage follower, and wherein the second operational amplifier is configured as a second voltage follower.

7. The wireless communication device of claim 5, wherein the first transconductance amplifier and the second transconductance amplifier are coupled in parallel to the adder, wherein the adder comprises a direct current (DC) current source and a resistor coupled to a common mode voltage between a source and a drain of the first switch.

8. The wireless communication device of claim 5, wherein the first operational amplifier is configured as a half-wave rectifier, and wherein the second operational amplifier is configured as an inverting half-wave rectifier.

9. The wireless communication device of claim 1, wherein the first absolute value circuit is coupled to a common mode voltage between a source and a drain of the first switch, and wherein the first gate driving circuit comprises:
a full-wave rectifier coupled to the common mode voltage;
an adder coupled to the full-wave rectifier, the adder further coupled to a direct current (DC) voltage and the common mode voltage, wherein an output of the adder is coupled to the gate of the first switch.

10. The wireless communication device of claim 9, wherein the full-wave rectifier comprises an analog voltage full-wave rectifier.

11. The wireless communication device of claim 1, wherein the first audio signal amplifier, the multiplexing circuitry, and the first switch are implemented on a coder decoder (codec) chip.

12. The wireless communication device of claim 1, wherein the data and audio plug comprises a universal serial bus (USB) plug.

13. The wireless communication device of claim 1, further comprising: a coder decoder (codec) chip that includes the set of wires, the first audio signal amplifier, and the multiplexing circuitry, and wherein the first switch is included in the multiplexing circuitry.

14. A method for operating wireless communication device having a first metal oxide semiconductor (MOSFET) switch implemented between a first audio signal amplifier and an application processor, the method comprising:
isolating the first audio signal amplifier from the application processor, including applying a first gate control signal to the first MOSFET switch at a first voltage level that turns off the first MOSFET switch; and
linearizing the first MOSFET switch, including applying the first gate control signal to the first MOSFET switch at a second voltage level during an ON state of the first MOSFET switch, wherein linearizing the first MOSFET switch includes generating a first absolute value waveform from a first signal, wherein the first gate control signal includes the first absolute value waveform.

15. The method of claim 14, wherein generating the first absolute value waveform comprises:
generating a half-wave rectified positive signal from the first signal;
generating a half-wave rectified negative signal from the first signal;
converting the half-wave rectified positive signal to a first current;
converting the half-wave rectified negative signal to a second current; and
adding the first current and the second current to a direct current (DC) current.

16. The method of claim 14, wherein generating the first absolute value waveform is performed in an analog voltage domain, wherein the first absolute value waveform is added to a direct current (DC) voltage and an absolute value voltage.

17. The method of claim 14, wherein the first signal comprises a digital audio signal, and wherein generating the first absolute value waveform is performed in a digital voltage domain, including inputting the digital audio signal to a digital filter, wherein the digital filter performs an absolute value function.

18. The method of claim 14, wherein the first signal comprises a common mode voltage between a source and a drain of the first MOSFET switch.

19. The method of claim 14, wherein the first MOSFET switch corresponds to a first audio channel, the method further comprising linearizing a second MOSFET switch corresponding to a second audio channel.

20. A wireless communication device comprising:
means for running an operating system;
means for amplifying analog audio signals;
means for coupling the means for running the operating system and the means for amplifying analog audio signals to a set of wires;
a data and audio plug coupled to the set of wires;
a first transistor coupled between the means for running the operating system and the means for amplifying analog audio signals; and
means for linearizing operation of the first transistor, including means for generating a gate control signal from a full-wave rectified signal.

21-30. (canceled)
